(19) United States
(12) Patent Application Publication
(10) Pub. No.: US 2015/0354896 A1
(43) Pub. Date: Dec. 10, 2015

(54) CRUCIBLE

(71) Applicant: BOE Technology Group Co., Ltd., Beijing (CN)

(72) Inventor: Peng Zhang, Beijing (CN)

(21) Appl. No.: 14/434,980

(22) PCT Filed: Aug. 26, 2014
(86) PCT No.: PCT/CN2014/085198

§ 371 Date: Apr. 10, 2015

(30) Foreign Application Priority Data
Mar. 6, 2014 (CN) 201410081299.8

(51) Int. Cl. F27B 14/10; C23C 16/448

(52) U.S. Cl. CPC F27B 14/10; C23C 16/4485; F27B 2014/104

(57) ABSTRACT

Embodiments of the invention disclose a crucible. The crucible comprises: a crucible body; and at least one heat conductive sheet disposed on an inner side wall of the crucible body. The at least one heat conductive sheet has at least one opening. The crucible is specifically used for evaporating process, and can improve the heating uniformity of the evaporation materials and prevent the evaporation material from local spurting.

### CROSS-REFERENCE TO RELATED APPLICATION

This Application is a Section 371 National Stage Application of International Application No. PCT/CN2014/085198, filed Aug. 26, 2014, which has not yet published, which claims priority to Chinese Application No. 201410081299.8, filed Mar. 6, 2014, in Chinese, the contents of which are hereby incorporated by reference in their entirety.

### FIELD OF THE INVENTION

The present invention relates to manufacturing technology field of display devices, and especially to a crucible.

### BACKGROUND OF THE INVENTION

Organic Light-Emitting Diode (OLED) display technology is considered as the next generation of display technology, because OLED display screens can provide advantages as follows: thin thickness, light weight, wide visual angle, active light-emitting, continuously adjustable color of emitted light, low cost, quick response, low energy consumption, low driving voltage, wide operating temperature range, simple production process, high light-emitting efficiency, flexible display, and the like.

An evaporation process is typically used for forming OLED devices on a substrate. During such evaporation process, a material to be evaporated is heated in a vacuum environment so that the material is melted and evaporated into steam, then the steam is deposited or coagulated when it meets a substrate of low temperature, and then a film of the material is formed on a surface of the substrate, and a function layer of the OLED devices is thereby formed.

Currently, heating of the evaporation material is mainly conducted through resistance heating or electron beam heating. A heat source used can be considered as a point heat source, and a material, such as an organic material or a metallic material, is heated and evaporated in a crucible.

Since the point heat source is typically used, the crucible is heated non-uniformly. In this circumstance, if the crucible has bad heat conductivity, then a non-uniform temperature distribution of the crucible is resulted at different locations thereof, so that a portion of the material, as compared with other portions of the material, at a location having a high temperature will be evaporated (or sublimed) more quickly such that more atoms or atomic groups will be generated and the evaporation process becomes unstable. Further, spurting phenomena may be caused during the evaporation process and thereby uniform thickness of the film formed on the substrate is adversely affected, and in turn, yield rate of evaporation products is adversely affected and production cost thereof is increased.

In order to solve the above technical problems, there is a need for an improved crucible within which an evaporation material can be evenly heated and thereby a local spurting of the material is prevented.

### SUMMARY OF THE INVENTION

An object of the present invention is to provide an improved crucible within which an evaporation material can be evenly heated and thereby a local spurting of the evaporation material is prevented.

According to one embodiment of the present invention, there is provided a crucible. The crucible comprises: a crucible body; and at least one heat conductive sheet disposed on an inner side wall of the crucible body. The at least one heat conductive sheet has at least one opening.

According to one embodiment of the present invention, the at least one heat conductive sheet is disposed in parallel with a plane in which an open end of the crucible body lies.

According to one embodiment of the present invention, the at least one opening comprises at least one notch formed at a peripheral region of the heat conductive sheet.

According to one embodiment of the present invention, the at least one opening comprises at least one inner hole formed in the heat conductive sheet.

According to one embodiment of the present invention, the heat conductive sheet is fixed to the inner side wall of the crucible body through welding or adhesives.

According to one embodiment of the present invention, the inner side wall of the crucible body is provided with a protrusion, and the at least one heat conductive sheet is supported on the protrusion.

According to one embodiment of the present invention, the crucible body and the at least one heat conductive sheet are integrally formed. Further, the crucible body and the at least one heat conductive sheet are formed from a same kind of metal material.

According to one embodiment of the present invention, the at least one heat conductive sheet is made from any one of titanium, tungsten, tantalum, and molybdenum.

According to one embodiment of the present invention, the at least one heat conductive sheet comprises two or more heat conductive sheets which are spaced apart from one another by a distance and are disposed in parallel with the plane in which the open end of the crucible body lies.

According to one embodiment of the present invention, shapes of openings in the two or more heat conductive sheets are different from one another.

According to a further embodiment of the present invention, shapes of openings in the two or more heat conductive sheets are different from one another, at least one of heat conductive sheets is substantially configured for heat conduction, and other heat conductive sheets are substantially configured for adjusting steam flows.

With the crucible of the invention, when heating and evaporation processes are conducted with the crucible, heat is transferred from a region having a relatively high temperature to another region having a relatively low temperature through the at least one heat conductive sheet within the crucible body, such that temperatures at respectively portions of the crucible is uniform, the evaporation material is uniformly heated, and local spurting of the evaporation material is prevented, and yield rate of evaporation products is increased. Additionally, the shape of openings of the heat conductive sheets can be designed so as to ensure that the steam(s) composed of atoms, molecules, and atomic groups generated by melting or sublimation of the evaporation material can pass through the at least one heat conductive sheet, and to control or adjust the steam flow(s) as expected.

### BRIEF DESCRIPTION OF THE DRAWINGS

In order to explicitly describe the technical solutions as recorded in embodiment(s) of the present invention and in the prior art, a brief description of the drawings as used in the embodiments is provided as follows. Obviously, the drawings as discussed below are only some examples of the present invention, and on the basis of the drawings, other drawings of the invention can be obtained by one skilled in the art without a creative work.

FIG. 1 is an illustrative structural drawing showing a crucible according to a first embodiment of the present invention;

FIG. 2 is an illustrative structural drawing showing a crucible according to a second embodiment of the present invention;

FIG. 3 is an illustrative structural drawing showing a crucible according to a third embodiment of the present invention;

FIG. 4 is an illustrative structural drawing showing a crucible according to a fourth embodiment of the present invention.

### A LIST EXPLANATION OF REFERENCE NUMBERS

1: crucible body

2: heat conductive sheet

11: open end

12: protrusion

21: opening

### DETAILED DESCRIPTION OF PREFERRED EMBODIMENTS OF THE INVENTION

Technical solutions of embodiments of the present disclosure will be described clearly and fully hereinafter in detail with reference to the attached drawings, and obviously, the description only provides some not all embodiments of the present invention. All other embodiments of the invention obtained by one skilled in the art on the basis of described embodiments without a creative work shall fall within the scope of the invention.

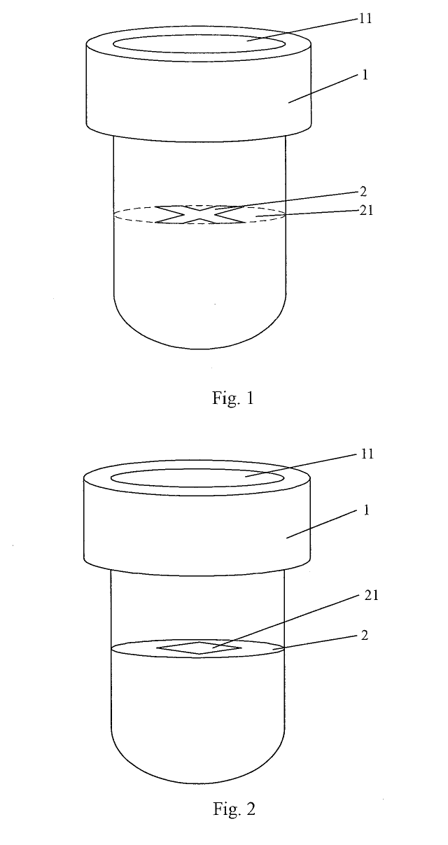

FIG. 1 is an illustrative structural drawing showing a crucible according to a first embodiment of the present invention. As shown in FIG. 1, the crucible comprises a crucible body 1 and a heat conductive sheet 2 disposed on inner side wall of the crucible body 1.

In the first embodiment, the crucible body 1 is generally in a cylindrical shape and comprises an open end 11 and a closed end opposite to the open end 11. A profile of the heat conductive sheet 2 is substantially consistent with the cross-section shape of the inner side wall of the crucible body 1, and the heat conductive sheet 2 can be placed into the crucible body 1 through the open end 11 and is disposed in parallel with a plane in which the open end 11 lies, that is, the heat conductive sheet is disposed perpendicular to an axial axis of the crucible body. The heat conductive sheet 2 has a certain thickness, which is not shown in the drawings. The heat conductive sheet 2 has at least one opening 21. In the first embodiment, the at least one opening 21 comprises at least one notch formed at a peripheral region of the heat conductive sheet 2. When the heat conductive sheet 2 is disposed within the crucible body 1, the at least one notch 21 is located between the heat conductive sheet 2 and the inner side wall of the crucible body 1, such that steams of an evaporation material can pass through the at least one notch 21 between the heat conductive sheet 2 and the inner side wall of the crucible body 1. The at least one notch 21 may be formed into various shapes including but not limited to a sector shape, a bow shape, and the like, such that the heat conductive sheet 2 may be in the shape of a crisscross (shown in FIG. 1), a strip, and the like. Therefore, characteristics such as flow rate and flow velocity of the steam coming out of the crucible body 1 can be adjusted through adjusting sizes and shapes of the at least one notch 21 of the heat conductive sheet 2, such that a film formed on a substrate has uniform thickness.

FIG. 2 is an illustrative structural drawing showing a crucible according to a second embodiment of the present invention. The crucible according to the second embodiment is substantially similar to the crucible according to the first embodiment except that the heat conductive sheet 2 has a different shape. Specifically, the at least one opening 21 of the heat conductive sheet 2 is at least one inner hole 21 of the heat conductive sheet 2. The at least one inner hole 21 may be formed in various shapes including but not limited to a polygon, an ellipse, a circle and the like. It should be understood that in other not shown embodiments, the at least one inner hole 21 may be located at different locations of the heat conductive sheet 2, and the number of the inner hole 21 in the heat conductive sheet 2 may vary. It should be understood that in other not shown embodiments, the heat conductive sheet 2 may have both the peripheral notch(s) 21 located between the heat conductive sheet 2 and the inner side wall of the crucible body 1 and the inner hole(s) 21 located inside the heat conductive sheet 2. All kinds of designs of the openings 21 shall fall within the scope of the invention, as long as steam(s) of the evaporation material can pass through the heat conductive sheet 2 and arrive at the substrate.

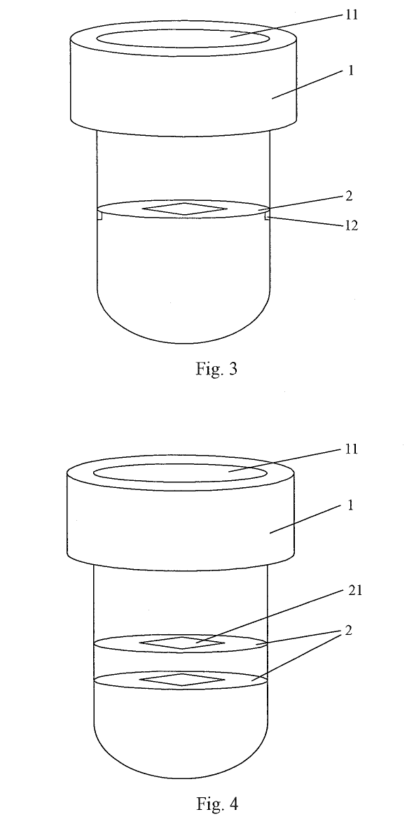

FIG. 3 is an illustrative structural drawing showing a crucible according to a third embodiment of the present invention. The crucible according to the third embodiment is substantially similar to the crucible according to the second embodiment except that the crucible body 1 according to the third embodiment further comprises a protrusion 12. In the third embodiment, the heat conductive sheet 2 and the crucible body 1 are separate parts from each other, and the heat conductive sheet 2 is disposed inside the crucible body for heat conduction only when the crucible body is not uniformly heated. As shown in FIG. 3, for example, the protrusion 12 may be provided on the inner side wall of the crucible body 1, and the heat conductive sheet 2 is disposed on and supported by the protrusion 12. The protrusion 12 may comprises a plurality of protruding parts extending radially inwards from the inner side wall of the crucible body 1, or the protrusion 12 may comprises a ring shaped boss extending radially inwards as a whole from the inner side wall of the crucible body 1.

In other embodiments of the invention, the heat conductive sheet 2 may be fixedly provided on the inner side wall of the crucible body 1. For example, if the crucible body 1 is made from metal materials, the heat conductive sheet 2 can also be made from metal materials and fixed to the inner side wall of the crucible body 1 through, for example, welding or other methods. Of course, the heat conductive sheet 2 can be formed integrally with the crucible body 1. If the crucible is made from quartz or a ceramic, then the heat conductive sheet 2 may be fixedly disposed onto the inner side wall of the crucible body 1 through adhesive materials.

FIG. 4 is an illustrative structural drawing showing a crucible according to a fourth embodiment of the present invention. The crucible according to the fourth embodiment is substantially similar to the crucible according to the second embodiment except that the crucible according to the fourth embodiment comprises two heat conductive sheets 2. In the fourth embodiment, as shown in FIG. 4, two heat conductive sheets 2 are disposed inside the crucible body 1 and spaced apart from each other by a suitable distance, and both of the two heat conductive sheets 2 are disposed in parallel with the plane in which the open end 11 of the crucible body 1 lies. With such a configuration, a plurality of conductive sheets 2 are used to facilitate heat conduction between different peripheral portions of the crucible, so that temperatures at different portions of the crucible body 1 can be uniformized. At the same time, shapes of openings of the two heat conductive sheets 2 can be also designed respectively so as to adjust flow rate of steam(s) of the evaporation material passing through the heat conductive sheets, so that an even more stable steam can be obtained. The openings of the two heat conductive sheets 2 are the same, as shown in FIG. 4. However, in other unshown embodiments of the invention, each of the heat conductive sheets 2 may have different kinds of openings. For example, openings of one heat conductive sheet 2 are substantially configured to facilitate heat conduction, and openings of the other heat conductive sheet 2 are substantially configured to adjust the steam flow.

According to an aspect of the invention, the heat conductive sheet 2 is made from materials having high heat conductivity, for example, metals such as titanium, tungsten, tantalum, molybdenum and the like.

With the crucible disclosed in the above embodiments of the invention, when heating and evaporation processes are conducted with the crucible, heat is transferred from a region having a relatively high temperature to another region having a relatively low temperature through the heat conductive sheet within the crucible, such that temperatures at respective portions of the crucible body are uniform, the evaporation material is uniformly heated, and local spurting of the material is prevented, and yield rate of evaporation products is increased. Additionally, openings of the heat conductive sheets can be designed so as to ensure that the steam(s) composed of atoms, molecules, and atomic groups generated by the melting or the sublimation of the evaporation material can pass through the heat conductive sheet(s), and to control or adjust the steam flow(s) as expected.

Specific embodiments of the invention are described as above, and the invention is not limited thereto. It would be appreciated by those skilled in the art that all changes or modifications should fall with the scope of the invention without departing from the principles and spirit of the disclosure. Therefore, the scope of the invention should be defined by the scopes of the appended claims.

1. A crucible, comprising:
a crucible body; and
at least one heat conductive sheet disposed on an inner side wall of the crucible body,
wherein the at least one heat conductive sheet has at least one opening.

2. The crucible according to claim 1, wherein
the heat conductive sheet is disposed in parallel with a plane in which an open end of the crucible body lies.

3. The crucible according to claim 1, wherein
the at least one opening comprises at least one notch formed at a peripheral region of the heat conductive sheet.

4. The crucible according to claim 1, wherein
the at least one opening comprises at least one inner hole formed in the heat conductive sheet.

5. The crucible according to claim 1, wherein
the heat conductive sheet is fixed to the inner side wall of the crucible body through welding or adhesives.

6. The crucible according to claim 1, wherein
the inner side wall of the crucible body is provided with a protrusion, and the at least one heat conductive sheet is supported on the protrusion.

7. The crucible according to claim 1, wherein
the crucible body and the at least one heat conductive sheet are integrally formed.

8. The crucible according to claim 7, wherein
the crucible body and the at least one heat conductive sheet are formed from the same kind of metal material.

9. The crucible according to claim 1, wherein
the at least one heat conductive sheet is made from any one of titanium, tungsten, tantalum, and molybdenum.

10. The crucible according to claim 1, wherein
the at least one heat conductive sheet comprises two or more heat conductive sheets which are spaced apart from one another by a distance and are disposed in parallel with the plane in which the open end of the crucible body lies.

11. The crucible according to claim 10, wherein
shapes of openings in the two or more heat conductive sheets are different from one another, wherein at least one of heat conductive sheets is substantially configured for heat conduction, and other heat conductive sheets are substantially configured for adjusting steam flows.
